(19) United States
(12) Patent Application Publication
(10) Pub. No.: US 2025/0076750 A1
(43) Pub. Date: Mar. 6, 2025

(54) PELLICLE MEMBRANE, PELLICLE ASSEMBLY INCLUDING THE SAME AND METHOD OF MANUFACTURING THE PELLICLE ASSEMBLY

(71) Applicant: SK hynix Inc., Icheon-si (KR)

(72) Inventor: Tae Joong HA, Icheon-si (KR)

(21) Appl. No.: 18/545,034

(22) Filed: Dec. 19, 2023

(30) Foreign Application Priority Data
Aug. 28, 2023 (KR) 10-2023-0112911

(51) Int. Cl. G03F 1/62

(52) U.S. Cl. CPC G03F 1/62

(57) ABSTRACT

A pellicle assembly may include a pellicle membrane and a pellicle border. The pellicle membrane may include at least one recess and at least one opening. The at least one recess may extend from an upper surface or a lower surface of the pellicle membrane. The at least one opening may penetrate from the upper surface to the lower surface of the pellicle membrane. The pellicle border may support the pellicle membrane.

### CROSS-REFERENCE TO RELATED APPLICATION

The present application claims priority under 35 U.S.C. § 119 (a) to Korean application number 10-2023-0112911, filed on Aug. 28, 2023, in the Korean Intellectual Property Office, which is incorporated herein by reference in its entirety.

### BACKGROUND

### 1. Technical Field

Various embodiments generally relate to a pellicle membrane, a pellicle assembly including the pellicle membrane, and a method of manufacturing the pellicle assembly.

### 2. Related Art

Recently, as a next generation semiconductor device and an LCD device may have been fined and highly integrated, a fine pattern may be formed by an exposing technology using an extreme ultraviolet (EUV).

The EUV exposing technology may be applied to a process for manufacturing a semiconductor device having no more than several nano meters. An EUV source may have an extinction coefficient higher than that of materials in the natural world differently from a laser source such as a KrF excimer laser, an ArF excimer laser, etc. Thus, in order to prevent a mask from being contaminated, a pellicle may be used in processing the exposing process using the EUV source.

The pellicle may include a membrane having a relatively thin thickness to avoid significantly reducing a transmissivity of the EUV light.

The transmissivity of the pellicle may be no more than about 88%. In this case, about 23% of a light loss may cause low productivity. In order to increase the transmissivity of the EUV light through the pellicle, it may be desirable to provide the membrane with a thin thickness.

However, the membrane may be damaged or a wrinkle may be formed at the membrane in forming the membrane by etching a silicon wafer, in handing the mask, or in vacuum pumping with mask.

### SUMMARY

Example embodiments provide a pellicle membrane that may be capable of decreasing an absorption of an EUV light and reducing an impact by a pressure difference.

Example embodiments also provide a pellicle assembly including the above-mentioned pellicle membrane.

Example embodiments still also provide a method of manufacturing the above-mentioned pellicle assembly.

According to example embodiments, there may be provided a pellicle assembly. The pellicle assembly may include a pellicle membrane with a first depth and a pellicle border. The pellicle membrane may include at least one recess and at least one opening. The at least one recess may extend from one or both of an upper surface and a lower surface of the pellicle membrane by a second depth. The at least one opening may penetrate from the upper surface to the lower surface in the pellicle membrane. The pellicle border may support the pellicle membrane.

In example embodiments, the pellicle membrane may include at least one light transmission layer.

In example embodiments, the pellicle membrane may include a plurality of light transmission layers which are stacked. The light transmission layers may each have a substantially same thickness and include a same material.

In example embodiments, the pellicle membrane may include a plurality of light transmission layers. At least one of the light transmission layers may include a material different from that of remaining light transmission layers.

In example embodiments, at least one of the light transmission layers may include a carbon-containing layer including at least one of graphene, graphite and carbon nanotube.

In example embodiments, the carbon-containing layer may be a central light transmission layer among the plurality of light transmission layers.

In example embodiments, the at least one opening may be positioned at an edge portion of the pellicle membrane adjacent to the pellicle border.

In example embodiments, the at least one recess may include a plurality of recesses. The recesses may have different depths.

According to example embodiments, there may be provided a pellicle membrane. The pellicle membrane may include a first light transmission layer. A plurality of openings may penetrate through the light transmission layer. A plurality of recesses may be disposed between adjacent openings among the plurality of openings.

In example embodiments, the at least one light transmission layer may have a first surface and a second surface. The recesses may include a first recess having a first depth from the first surface and a second recess having a second depth from the second surface.

In example embodiments, the membrane further includes a second light transmission layer interposed between the first recess and the second recess. The second light transmission layer may include a carbon-containing layer including at least one of graphene, graphite and carbon nanotube.

According to example embodiments, the pellicle membrane may include the recess and the opening to decrease an absorption amount of an EUV light and to improve a mechanical property of the pellicle membrane. The pellicle membrane may buffer an impact caused by a pressure difference so that the pellicle membrane may not be easily broken to extend a lift span of the pellicle membrane.

### BRIEF DESCRIPTION OF THE DRAWINGS

The above and another aspects, features and advantages of the subject matter of the present disclosure will be more clearly understood from the following detailed description taken in conjunction with the accompanying drawings, in which:

FIG. 1 is a cross-sectional view illustrating a pellicle assembly in accordance with example embodiments;

FIGS. 2, 3, 4, 5, 6, 7, 8, 9, 10, 11, 12, 13, and 14 are cross-sectional views illustrating pellicle assemblies in accordance with example embodiments;

FIG. 15 is a flow chart illustrating a method of manufacturing a pellicle assembly in accordance with example embodiments;

FIGS. 16A, 16B, 16C, and 16D are cross-sectional views illustrating a method of manufacturing a pellicle membrane in accordance with example embodiments;

FIGS. 17A, 17B, and 17C are cross-sectional views illustrating a method of manufacturing a pellicle membrane in accordance with example embodiments; and

FIGS. 18A, 18B, and 18C are cross-sectional views illustrating a method of manufacturing a pellicle membrane in accordance with example embodiments.

### DETAILED DESCRIPTION

Various embodiments of the present disclosure will be described in greater detail with reference to the accompanying drawings. The drawings are schematic illustrations of various embodiments (and intermediate structures). As such, variations from the configurations and shapes of the illustrations as a result, for example, of manufacturing techniques and/or tolerances, are possible. Thus, the described embodiments should not be construed as being limited to the particular configurations and shapes illustrated herein but may include deviations in configurations and shapes which do not depart from the spirit and scope of the present disclosure as defined in the appended claims.

Embodiments of the present disclosure are described herein with reference to cross-section and/or plan illustrations of idealized embodiments. However, embodiments of the present disclosure should not be construed as limiting the inventive concept. Although a few embodiments of the present disclosure will be shown and described, it will be appreciated by those of ordinary skill in the art that changes may be made in these embodiments without departing from the principles and spirit of the present disclosure.

As used herein, the term “configured” may refer to a size, shape, material composition, orientation, and arrangement of one or more of at least one structure and at least one apparatus facilitating operation of one or more of the structure and the apparatus in a pre-determined way.

As used herein, the terms “vertical,” “longitudinal,” “horizontal,” and “lateral” are in reference to a major plane of a structure and are not necessarily defined by earth's gravitational field. A “horizontal” or “lateral” direction is a direction that is substantially parallel to the major plane of the structure, while a “vertical” or “longitudinal” direction is a direction that is substantially perpendicular to the major plane of the structure. The major plane of the structure is defined by a surface of the structure having a relatively large area compared to other surfaces of the structure. With reference to the figures, a “horizontal” or “lateral” direction may be perpendicular to an indicated “Z” axis, and may be parallel to an indicated “X” axis and/or parallel to an indicated “Y” axis; and a “vertical” or “longitudinal” direction may be parallel to an indicated “Z” axis, may be perpendicular to an indicated “X” axis, and may be perpendicular to an indicated “Y” axis.

As used herein, features (e.g., regions, structures, devices) described as “neighboring” one another means and includes features of the disclosed identity (or identities) that are located most proximate (e.g., closest to) one another. Additional features (e.g., additional regions, additional structures, additional devices) not matching the disclosed identity (or identities) of the “neighboring” features may be disposed between the “neighboring” features. Put another way, the “neighboring” features may be positioned directly adjacent one another, such that no other feature intervenes between the “neighboring” features; or the “neighboring” features may be positioned indirectly adjacent one another, such that at least one feature having an identity other than that associated with at least one the “neighboring” features is positioned between the “neighboring” features. Accordingly, features described as “vertically neighboring” one another means and includes features of the disclosed identity (or identities) that are located most vertically proximate (e.g., vertically closest to) one another. Moreover, features described as “horizontally neighboring” one another means and includes features of the disclosed identity (or identities) that are located most horizontally proximate (e.g., horizontally closest to) one another.

As used herein, spatially relative terms, such as “beneath,” “below,” “bottom,” “bottom,” “above,” “upper,” “top,” “front,” “rear,” “left,” “right,” and the like, may be used for ease of description to describe one element's or feature's relationship to another element(s) or feature(s) as illustrated in the figures. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” may encompass both an orientation of above and below, depending on the context in which the term is used, which will be evident to one of ordinary skill in the art. The materials may be otherwise oriented (e.g., rotated 90 degrees, inverted, flipped) and the spatially relative descriptors used herein interpreted accordingly.

As used herein, the singular forms “a,” “an,” and “the” are intended to include the plural forms as well, unless the context clearly indicates otherwise.

As used herein, “and/or” includes any and all combinations of one or more of the associated listed items. As used herein, “at least one of . . . and” indicates a disjunctive list of each of items as well as possible combination(s). For example, “at least one of A and B” indicates “only A, or only B, or both A and B,” and “at least one of A, B, and C” indicates “only A, or only B, only C, or both A and B, or both A and C, or both B and C, or all of A and B and C.”

As used herein, the phrase “coupled to” refers to structures operatively connected with each other, such as electrically connected through a direct Ohmic contact or through an indirect connection (e.g., by way of another structure).

As used herein, the term “substantially” in reference to a given parameter, property, or condition means and includes to a degree that one of ordinary skill in the art would understand that the given parameter, property, or condition is met with a degree of variance, such as within acceptable tolerances. By way of example, depending on the particular parameter, property, or condition that is substantially met, the parameter, property, or condition may be at least 90.0 percent met, at least 95.0 percent met, at least 99.0 percent met, at least 99.9 percent met, or even 100.0 percent met.

As used herein, “about” or “approximately” in reference to a numerical value for a particular parameter is inclusive of the numerical value and a degree of variance from the numerical value that one of ordinary skill in the art would understand is within acceptable tolerances for the particular parameter. For example, “about” or “approximately” in reference to a numerical value may include additional numerical values within a range of from 90.0 percent to 110.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

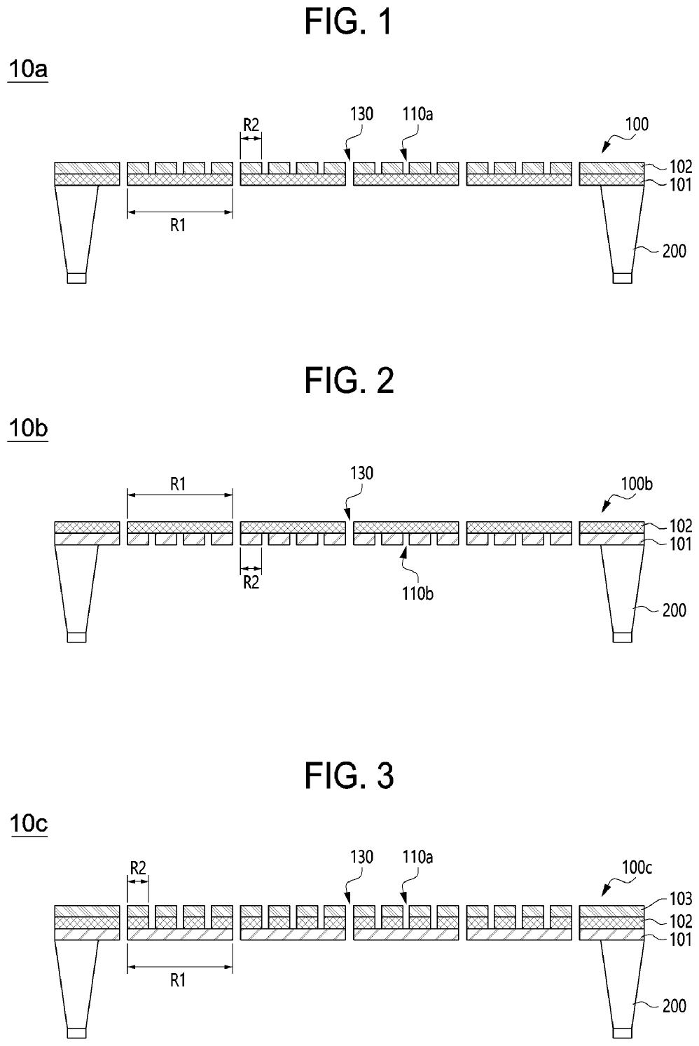

FIG. 1 is a cross-sectional view illustrating a pellicle assembly in accordance with example embodiments and FIGS. 2 to 14 are cross-sectional views illustrating pellicle assemblies in accordance with example embodiments.

Referring to FIG. 1, a pellicle assembly 10a may include a pellicle membrane 100 and a pellicle border 200.

The pellicle assembly 10a may be arranged over a photo mask to substantially prevent contamination of the photo mask. For example, the pellicle assembly 10a may be positioned between an object such as a photoresist film and the photo mask.

The pellicle membrane 100 may be configured to transmit light (e.g., EUV light) having a specific wavelength (e.g., about 13.6 nm).

The pellicle membrane 100 may include at least one light transmission layer. For example, the pellicle membrane 100 may include a plurality of stacked light transmission layers 101 and 102.

As shown in FIGS. 2 to 12, the pellicle membrane 100 may include a multi-stack structure having at least two light transmission layers (e.g., five light transmission layers 101˜105 in FIG. 9).

In example embodiments, each of the light transmission layers may include a compound having substantially the same composition. Alternatively, the light transmission layers may include compounds having different compositions. Further, at least one of the light transmission layers may include a compound having a composition and the remaining light transmission layers may include different compositions of compounds. For example, at least one of the light transmission layers of the pellicle membrane (e.g., the pellicle membrane 100 in FIG. 1) may include single crystalline silicon, polycrystalline silicon, non-crystalline silicon, silicon oxide, silicon carbon, silicon nitride, silicon carbon nitride, silicon oxynitride, silicon carbon oxide, etc. Alternatively, at least one of the light transmission layers of the pellicle membrane may include a compound including at least two of single crystalline silicon, polycrystalline silicon, non-crystalline silicon, silicon oxide, silicon carbon, silicon nitride, silicon carbon nitride, silicon oxynitride, silicon carbon oxide, etc.

At least one of the light transmission layers of the pellicle membrane may include at least one of molybdenum (Mo), tantalum (Ta), titanium (Ti), vanadium (V), cobalt (Co), copper (Cu), nickel (Ni), zirconium (Zr), niobium (Nb), palladium (Pd), platinum (Pt), iron (Fe), zinc (Zn), tin (Sn), chromium (Cr), manganese (Mn), cadmium (Cd), magnesium (Mg), lithium (Li), selenium (Se), hafnium (Hf), yttrium (Y), tungsten (W), graphene, graphite, carbon nanotube, chromium nitride (CrN), aluminum (AI), aluminum oxide (Al2O3), indium (In), boron (B), beryllium (Be), niobium (Nb), ruthenium (Ru), praseodymium (Pr), lanthanum (La), tellurium (Te), rhodium (Rh), europium (Eu), aluminum (Al), gallium (Ga), arsenic (As), antimony (Sb), and bismuth (Bi).

Further, at least one of the light transmission layers of the pellicle membrane may include a dichalcogenide transition metal material in the form of a two-dimensional single layer combining a transition metal and a chalcogen element in an MX2 structure. For example, the transition metal may include molybdenum (Mo) or tungsten (W). The dichalcogenide material may include, for example, sulfur(S), selenium (Se), or tellurium (Te). Additionally, the dichalcogenide material described above may be single-layered or multi-layered. In particular, at least one of the light transmitting layers is molybdenum disulfide (MoS2), molybdenum selenoid (MoSe2), tungsten disulfide (WS2), tungsten selenoid (WSe2), molybdenum ditelluride (MoTe2), and tungsten telluride, tungsten ditelluride (WTe2), or a mixture thereof. In particular, at least one of the light transmitting layers of the pellicle membrane may include at least one of the metal, metal alloy, non-metal, oxygen (O), nitrogen (N), and carbon (C). In addition, at least one of the light transmitting layers may include a porous material layer.

In example embodiments, the pellicle membrane (e.g., the pellicle membrane 100 in FIG. 1) may include at least one recess (e.g., recess 110a in FIG. 1 and recess 110b in FIG. 2) and a plurality of openings 130.

In example embodiments, the recess 110a and 110b may correspond to a groove having a depth less than a thickness of the pellicle membrane. Additionally, the recess 110a may correspond to an upper recess formed on an upper surface of the pellicle membrane. The recess 110b may correspond to a lower recess formed on a lower surface of the pellicle membrane. For example, the upper recess 110a may include an open surface toward the upper surface of the pellicle membrane and a bottom surface toward the lower surface of the pellicle membrane. In other words, the upper recess 110a may extend from the upper surface of the pellicle membrane, or the lower recess 110b may extend from the lower surface of the pellicle membrane, or both. Thus, the thickness of the pellicle membrane may be changed in accordance with the formation of the upper recess 110a, or the lower recess 110b, or both. Therefore, one or both of the recesses 110a and 110b on the upper and lower surface of the pellicle membrane may decrease an absorption amount of the EUV light and improve a transmission of the EUV light.

When the upper surface and the lower surface of the pellicle membrane face each other and are spaced apart from each other by a first depth, at least one recess may extend from one or both of the upper surface and the lower surface by a second depth smaller than the first depth. In example embodiments, the depth of the recess (e.g., the upper recess 110a in FIG. 1, the lower recess 110b in FIG. 2) may be about 10% to about 90%, preferably, about 30% to about 60% of the thickness of the pellicle membrane. For example, when the thickness of the pellicle membrane without the recess and the opening 130 may be about 100 nm, the depth of the recesses may be about 10 nm to about 90 nm. Thus, a thickness of a portion of the pellicle membrane where the recess may be formed may be about 10 nm to about 90 nm. The light transmission layer may remain on the bottom surface of the recess to prevent the mechanical property of the pellicle membrane from being significantly decreased compared to a pellicle membrane without having the recess.

In example embodiments, the pellicle membrane may include the upper recess 110a, or the lower recess 110b, or the upper and lower recesses 110a and 110b. A planar structure of the recess 110a and 110b may be a circular shape, an elliptical shape, a polygonal shape, etc.

For example, the recess may have a size (e.g., a width, a diameter, etc.) of about 5 nm to about 30,000 nm, but embodiments of the present disclosure are not limited thereto. In other words, each of a plurality of recesses may have a width of about 5 nm to about 30,000 nm. The width of the recess 110a and 110b may be changed in accordance with the light absorption by properties of the light transmission layers in the pellicle membrane. Further, the width of the recess 110a and 110b may be substantially uniform or different from each other along a thickness direction of the pellicle membrane.

In example embodiments, the numbers of the recess 110a and 110b may be about 1 to about 10⁹ by 1,000 μm² in accordance with the light absorption and the mechanical property of the pellicle membrane.

The opening 130 may be formed through the pellicle membrane. Fluid (e.g., air) over and under the pellicle membrane may flow through the opening 130. For example, the opening 130 may buffer an impact caused by a pressure difference applied to the pellicle membrane between a process for forming a pellicle assembly (e.g., pellicle assemblies 10a˜10n in FIGS. 1 to 14) and a process for transferring the pellicle assembly 10a˜10n. As a result, the opening 130 may substantially prevent the pellicle membrane from being damaged. An upper structure of the opening 130 may be a circular shape, an elliptical shape, a polygonal shape, etc. A number and a width of the opening 130 may be changed in accordance with the size and the light absorption of the pellicle membrane. In other words, the number of a plurality of openings 130 and a size (e.g., a width, a diameter) of each of the plurality of openings 130 may vary in accordance with the size and the light absorption of the pellicle membrane. For example, the number of the opening 130 may be about 1 to about 10⁹ by 1,000 μm². The width of the opening 130 may be about 5 nm to about 30,000 nm.

When the number of the opening 130 may be less than a set number, the impact buffering effect may be significantly decreased. In contrast, when the number of the opening 130 may be greater than the set number, the mechanical property of the pellicle membrane may be significantly deteriorated. In some embodiments, a ratio of a total area occupied by the openings 130 to the entire area of a surface (e.g., the upper surface or lower surface) of the pellicle membrane may be in a range from 0.5% to 10.5%, 1% to 9%, or 3% to 7%.

Particularly, widths of a plurality of openings 130 may be same or different from each other with respect to the thickness direction of the pellicle membrane. For example, a width of each of a plurality of openings 130 in a direction substantially perpendicular to a thickness direction may be kept substantially constant or vary along the thickness direction.

In example embodiments, the recess 110a and 110b and the opening 130 may be formed by an etching process using a mask.

The recess 110a and 110b and/or the opening 130 may be spaced apart from each other by a uniform gap. Alternatively, the recess 110a and 110b and the opening 130 may be randomly arranged. The pellicle border 200 may be arranged at the edge portion of the pellicle membrane to support the pellicle membrane. The pellicle border 200 may maintain the photo mask and the pellicle membrane. For example, the pellicle border 200 may be positioned at an edge portion of the lower surface of the pellicle membrane. In example embodiments, the opening 130 may be arranged at an edge region adjacent to the pellicle border 200. Thus, when transferring the pellicle assembly, an impact applied to the pellicle membrane may be reduced. Specifically, when the openings 130 are arranged only at one or more edge regions of the pellicle membrane, where each of the edge regions may be formed within in a given distance from an inner edge of the pellicle border 200. For example, the given distance in a specific direction may be in a range not greater than 20% of the entire width of the pellicle membrane in the specific direction. When the distance is greater than 20% of the entire width of the pellicle membrane, the edge region may have an excessively large area to significantly deteriorate mechanical properties (e.g., bending modulus) of the pellicle membrane.

In example embodiments, stacked numbers of the light transmission layers in the pellicle membrane may not be restricted within a specific number. A total thickness of the pellicle membrane may be about 5 nm to about 300 nm considered the light transmittance and the mechanical property. The pellicle border 200 may include a material having good heat dissipation characteristics. The pellicle border 200 may define a region to which a metal frame may be attached. The metal frame may be attached to a side surface or a lower surface of the pellicle border 200 to fix the pellicle membrane. The metal frame may be used for a handling region for the pellicle assembly (e.g., pellicle assemblies 10a and 10b in FIGS. 1 and 2), or a protection member, or both. The metal frame may include aluminum, aluminum titanium, etc.

The metal frame may include a material having strong mechanical strength. The metal frame may have a shape, a dimension and a configuration configured to fix the pellicle membrane. The metal frame may have a thickness for preventing a weight of the pellicle assembly from being significantly increased without an image of a contaminant.

For example, referring to FIG. 1, the pellicle assembly 10a may include the pellicle membrane 100. The pellicle membrane 100 may include a first light transmission layer 101 and a second light transmission layer 102 stacked on the first light transmission layer 101.

The pellicle membrane 100 including the first light transmission layer 101 and the second light transmission layer 102 may include a plurality of openings 130 and a plurality of upper recesses 110a. The openings 130 may be spaced apart from each other by a first gap R1. The upper recesses 110a may be arranged between the openings 130. The upper recesses 110a may be spaced apart from each other by a second gap R2. The second gap may be narrower than the first gap. A plurality of first gaps may be substantially the same. Alternatively, the first gaps may be different from each other. A plurality of second gaps may be substantially the same. Alternatively, the second gaps may be different from each other. The upper recess 110a may be formed by etching the second light transmission layer 102. The opening 130 may be formed by etching the first light transmission layer 101 and the second light transmission layer 102.

Referring to FIG. 2, the pellicle assembly 10b may include the pellicle membrane 100b. The pellicle membrane 100b may include a first light transmission layer 101 and a second light transmission layer 102 stacked on the first light transmission layer 101.

The pellicle membrane 100b may include a plurality of openings 130 and a plurality of lower recesses 110b. The openings 130 may be spaced apart from each other by a first gap R1. The lower recesses 110b may be arranged between the openings 130. The lower recesses 110b may be spaced apart from each other by a second gap R2. The lower recess 110b may be formed by etching the first light transmission layer 101. The opening 130 may be formed by etching the first light transmission layer 101 and the second light transmission layer 102.

Referring to FIG. 3, the pellicle assembly 10c may include the pellicle membrane 100c. The pellicle membrane 100c may include a first light transmission layer 101, a second light transmission layer 102 and a third light transmission layer 103 sequentially stacked.

The pellicle membrane 100c may include a plurality of openings 130 and a plurality of upper recesses 110a. The openings 130 may be spaced apart from each other by a first gap R1. The upper recesses 110a may be arranged between the openings 130. The upper recesses 110a may be spaced apart from each other by a second gap R2. The upper recess 110a may be formed by etching the second and third light transmission layers 102 and 103. A depth of the upper recess 110a may correspond to a sum of thicknesses of the second and third light transmission layers 102 and 103. That is, a thickness of a portion in the pellicle membrane 100c where the upper recess 110a may be formed may be a thickness of the first light transmission layer 101. The opening 130 may be formed by etching the first to third light transmission layers 101, 102 and 103.

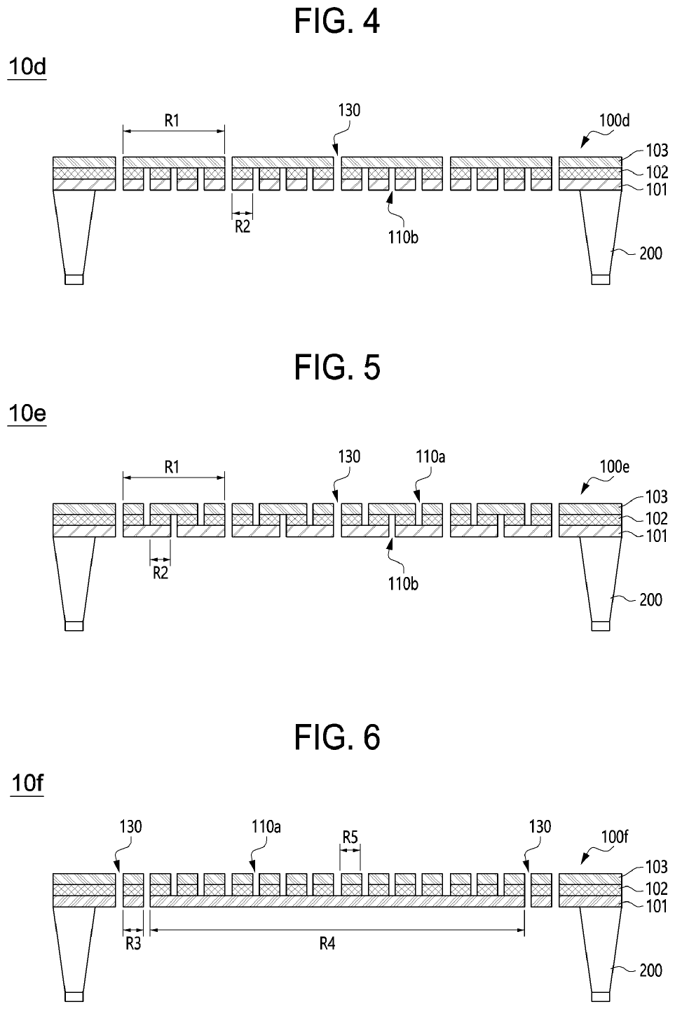

Referring to FIG. 4, the pellicle assembly 10d may include the pellicle membrane 100d. The pellicle membrane 100d may include a first light transmission layer 101, a second light transmission layer 102 and a third light transmission layer 103 sequentially stacked.

The pellicle membrane 100d may include a plurality of openings 130 and a plurality of lower recesses 110b. The openings 130 may be spaced apart from each other by a first gap R1. The lower recesses 110b may be arranged between the openings 130. The lower recesses 110b may be spaced apart from each other by a second gap R2. The lower recess 110b may be formed by etching the first and second light transmission layers 101 and 102. A depth of the lower recess 110b may correspond to a sum of thicknesses of the first and second light transmission layers 101 and 102. That is, a thickness of a portion in the pellicle membrane 100d where the lower recess 110b may be formed may be a thickness of the third light transmission layer 103. The opening 130 may be formed by etching the first to third light transmission layers 101, 102 and 103.

In example embodiments, the upper recess 110a in FIG. 3 and the lower recess 110b in FIG. 4 may have the depth corresponding to the thickness of the two light transmission layers, but embodiments of the present disclosure are not limited thereto. For example, the upper recess 110a in FIG. 3 and the lower recess 110b in FIG. 4 may have the depth corresponding to one light transmission layer.

Referring to FIG. 5, the pellicle assembly 10e may include the pellicle membrane 100e. The pellicle membrane 100e may include a first light transmission layer 101, a second light transmission layer 102 and a third light transmission layer 103 sequentially stacked.

The pellicle membrane 100e may include a plurality of openings 130, at least one upper recess 110a and at least one lower recess 110b. The openings 130 may be spaced apart from each other by a first gap R1.

The upper recess 110a and the lower recess 110b may be alternately arranged between the adjacent openings 130. The upper recess 110a and the lower recess 110b may be spaced apart from each other by a second gap R2. By alternately arranging the upper recesses 110a and the lower recesses 110b, the pellicle membrane 100e according to the embodiment of FIG. 5 may have more uniform mechanical properties for an upper portion and a lower portion thereof, compared to the pellicle membranes 100c in FIGS. 3 and 100d and FIG. 4.

For example, the upper recess 110a may be formed by etching the second and third light transmission layers 102 and 103. The lower recess 110b may be formed by etching the first and second light transmission layers 101 and 102. The opening 130 may be formed by etching the first to third light transmission layers 101, 102 and 103.

Referring to FIG. 6, the pellicle assembly 10f may include the pellicle membrane 100f. The pellicle membrane 100f may include a first light transmission layer 101, a second light transmission layer 102 and a third light transmission layer 103 sequentially stacked.

The pellicle membrane 100f may include a plurality of openings 130 and a plurality of upper recesses 110a. In an embodiment, a gap R4 between a first adjacent pair of openings 130 may be greater than a gap R3 between a second adjacent pair of openings 130, where the first adjacent pair of openings 130 are located farther from the pellicle border 200 than the second adjacent pair of openings 130. Since a relatively large number of the openings 130 are formed proximate to the pellicle border 200, the openings 130 may allow fluid flow through the pellicle membrane 100f to keep a pressure difference across the pellicle membrane 100f relatively small, while preventing mechanical properties of the pellicle membrane 100j from being significantly deteriorated. For example, first openings among the total openings 130 adjacent to the pellicle border 200 may be spaced apart from each other by a third gap R3. Second openings among the total openings 130 remote from the pellicle border 200 may be spaced apart from each other by a fourth gap R4 wider than the third gap R3. The upper recesses 110a may be arranged between the openings 130 having the fourth gap R4. The upper recesses 110a may be spaced apart from each other by a fifth gap R5. The fifth gap R5 may be narrower than the third gap R3 and the fourth gap R4.

In example embodiments, FIG. 6 may show the upper recesses 110a having the fifth gap R5, but embodiments of the present disclosure are not limited thereto. For example, other embodiments may include the lower recesses (not shown) in place of the upper recesses 110a may be spaced apart from each other by the fifth gap R5.

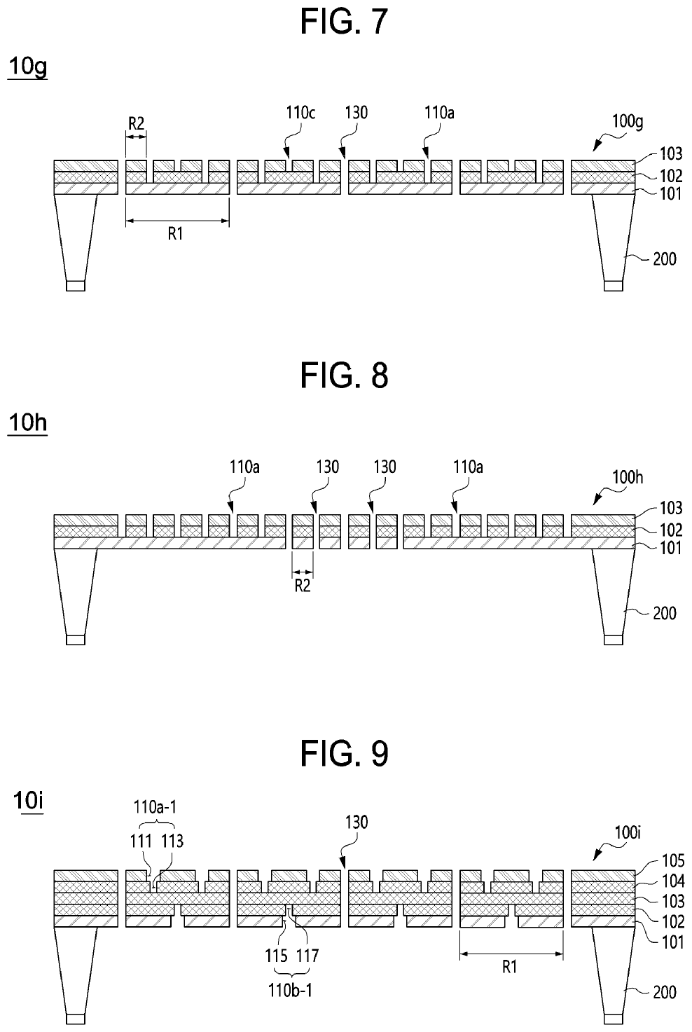

Referring to FIG. 7, the pellicle assembly 10g may include the pellicle membrane 100g. The pellicle membrane 100g may include a first light transmission layer 101, a second light transmission layer 102 and a third light transmission layer 103 sequentially stacked.

The pellicle membrane 100g may include a plurality of openings 130 and first and second upper recesses 110a and 110c. The openings 130 may be spaced apart from each other by the first gap R1. The first and second recesses 110a and 110c may be alternately arranged between the adjacent openings 130. The first and second upper recesses 110a and 110c may have different depths. The first and second upper recesses 110a and 110c may be spaced apart from each other by the second gap R2. The first upper recess 110a may be formed by etching the second and third light transmission layers 102 and 103. The second upper recess 110c may be formed by etching the third light transmission layer 103. By alternately arranging the first and second upper recesses 110a and 110c and making the second upper recesses 110c have a smaller depth than the first upper recesses 110a, the pellicle membrane 100g according to the embodiment in FIG. 7 may have improved mechanical properties (e.g., increased bending modulus) compared to the embodiment in FIG. 3 having only the first upper recesses 110a.

As shown in FIG. 8, the openings 130 may be arranged in a region of the pellicle membrane 100h, which may be remote from the pellicle border 200, denser than a region of the pellicle membrane 100h, which may be adjacent to the pellicle border 200.

Referring to FIG. 9, the pellicle assembly 10i may include the pellicle membrane 100i. The pellicle membrane 100i may include a first light transmission layer 101, a second light transmission layer 102, a third light transmission layer 103, a fourth light transmission layer 104 and a fifth light transmission layer 105 sequentially stacked.

The pellicle membrane 100i may include a plurality of openings 130 and a plurality of recesses. The openings 130 may be spaced apart from each other by the first gap R1. The recesses may include at least one upper recess 110a-1 and at least one lower recess 110b-1. The upper recess 110a-1 and the lower recess 110b-1 may be alternately arranged. The upper recesses 110a-1 may have different widths or diameters. The lower recesses 110b-1 may have different widths or diameters.

For example, the upper recess 110a-1 may be formed by etching the fourth and fifth light transmission layers 104 and 105. A width of a hole 111 in the fifth light transmission layer 105 may be wider or narrower than a width of a hole 113 in the fourth light transmission layer 104.

For example, the lower recess 110b-1 may be formed by forming holes 115 and 117 through the first and second light transmission layers 101 and 102. A width of the hole 115 in the first light transmission layer 101 may be wider or narrower than a width of the hole 117 in the second light transmission layer 102. Further, a diameter of upper and lower surfaces of the upper and lower recesses 110a-1 and 110b-1 to which a light may be incident may be greater than an inner diameter of the upper and lower recesses 110a-1 and 110b-1.

In an embodiment, a recess may include an outer hole and an inner hole that have a different width (e.g., a diameter) from each other. For example, referring to FIG. 9, a width of an outer hole 111 formed in the fifth light transmission layer 105 may be greater than that of an inner hole 113 in the fourth light transmission layer 104. Similarly, a width of an outer hole 115 formed in the first light transmission layer 101 may be greater than that of an inner hole 117 formed in the second light transmission layer 102. For example, the width (e.g., diameter) of the hole 111 adjacent to the upper surface and the hole 115 adjacent to the lower surface may be about 10 nm to about 300 nm. The width of the holes 113 and 117 adjacent to the third light transmission layer 103 may be about 5 nm to about 200 nm.

In example embodiments, the thicknesses of the first to fifth light transmission layers 101˜105 may be substantially equal to or different from each other. The widths of the holes 111, 113, 115 and 117 in the light transmission layers may be controlled based on the thicknesses of the first to fifth light transmission layers 101˜105.

In example embodiments, in FIG. 9, the upper recess 110a-1 and the lower recess 110b-1 may be alternately arranged, but embodiments of the present disclosure are not limited thereto. Further, the light transmission layers may include the five layers, but embodiments of the present disclosure are not limited thereto.

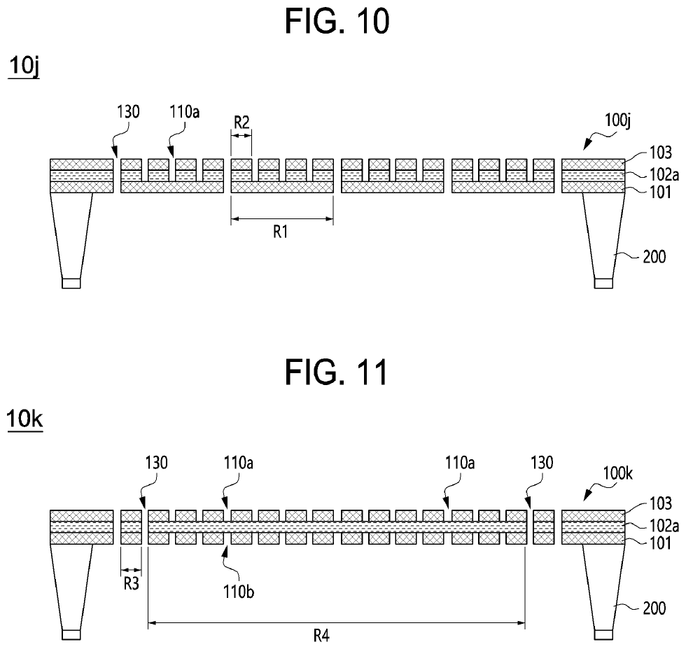

Referring to FIGS. 10 to 12, pellicle assembles 10j, 10k and 10l may include pellicle membranes 100j, 100k and 100l, respectively. Each of the pellicle membranes 100j, 100k and 100l may include first to third light transmission layers 101, 102a and 103. At least one of the first to third light transmission layers 101 and 102a and 103 may include a carbon-containing material such as graphene, graphite, carbon nanotube, etc. In example embodiments, a central light transmission layer among the first to third light transmission layers 101, 102a and 103, i.e., the second light transmission layer 102a may include the carbon-containing layer. Thus, the pellicle membranes 100j, 100k and 100l may have desirable mechanical strength by the carbon-containing material as well as good light transmittance. Further, durability of the pellicle membranes 100j, 100k and 100l may substantially prevent formation of a wrinkle. When the pellicle membranes 100j, 100k and 100l may be broken, the pellicle membranes 100j, 100k and 100l may be broken into parts each having a relatively large size to substantially prevent generations of chips from the broken pellicle membranes 100j, 100k and 100l. Further, the pellicle membranes 100j, 100k and 100l may not be rolled.

Referring to FIG. 10, the pellicle membrane 100j may include the first light transmission layer 100, a carbon-containing second light transmission layer 102a and the third light transmission layer 103. The pellicle membrane 100j may include a plurality of openings 130 and the upper recesses 110a. The openings 130 may be spaced apart from each other by the first gap R1. The upper recesses 110a may be positioned between the openings 130. The upper recesses 110a may be spaced apart from by the second gap R2. The upper recesses 110a may be formed by etching the second and third light transmission layers 102a and 103.

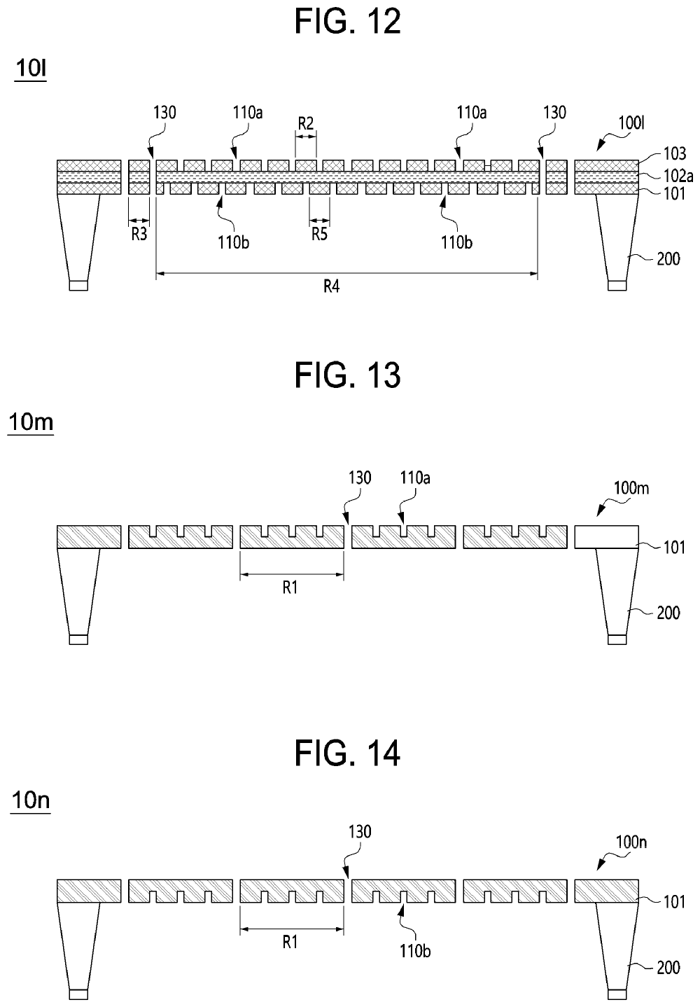

Referring to FIG. 11, the pellicle membrane 100k may include the first light transmission layer 100, a carbon-containing second light transmission layer 102a and the third light transmission layer 103. The pellicle membrane 100j may include a plurality of openings 130, the upper recesses 110a and the lower recesses 110b. For example, first openings among the total openings 130 adjacent to the pellicle border 200 may be spaced apart from each other by the third gap R3. Second openings among the total openings 130 remote from the pellicle border 200 may be spaced apart from each other by the fourth gap R4 wider than the third gap R3. The upper recesses 110a may be arranged between the openings 130 having the fourth gap R4. The upper recesses 110a may be spaced apart from each other by the fifth gap R5. The lower recesses 110b may be arranged between the openings 130 having the fourth gap R4. The lower recesses 110b may be spaced apart from each other by the fifth gap R5. In example embodiments, the upper recesses 110a may face the lower recesses 110b. Alternatively, as shown in FIG. 12, the upper recesses 110a and the lower recesses 110b may be arranged in a non-correspondence pattern.

For example, the upper recesses 110a may be formed by etching the third light transmission layer 103. The lower recesses 110b may be formed by etching the first light transmission layers 101. Although the recesses 110a and 110b may be formed on the upper and lower surfaces of the pellicle membrane 100k, the pellicle membrane 100k may have strong mechanical strength due to the carbon-containing second light transmission layer 102a.

Referring to FIGS. 13 and 14, pellicle assemblies 10m and 10n may include pellicle membranes 100m and 100n. Each of the pellicle membranes 100m and 100n may include a single light transmission layer 101.

Referring to FIG. 13, the pellicle membrane 100m may include a plurality of openings 130 and the upper recesses 110a. The openings 130 may be spaced apart from each other by the first gap R1. The upper recesses 110a may be arranged between the openings 130. The upper recesses 110a may be formed by etching an upper surface of the single light transmission layer 101.

Referring to FIG. 14, the pellicle membrane 100n may include a plurality of openings 130 and the lower recesses 110b. The openings 130 may be spaced apart from each other by the first gap R1. The lower recesses 110b may be arranged between the openings 130. The lower recesses 110b may be formed by etching a lower surface of the single light transmission layer 101.

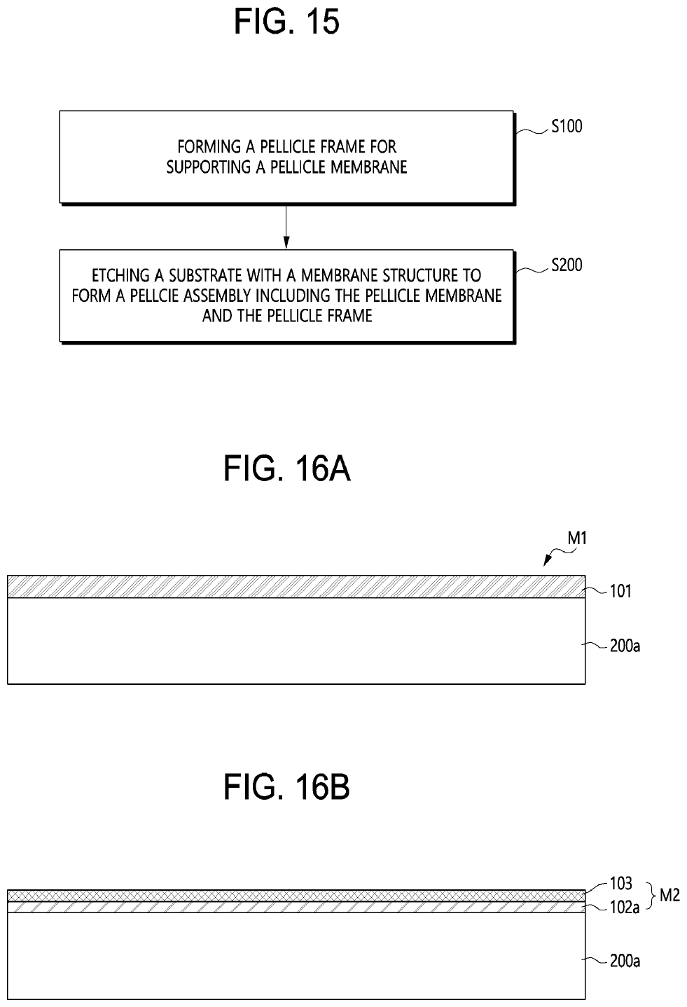

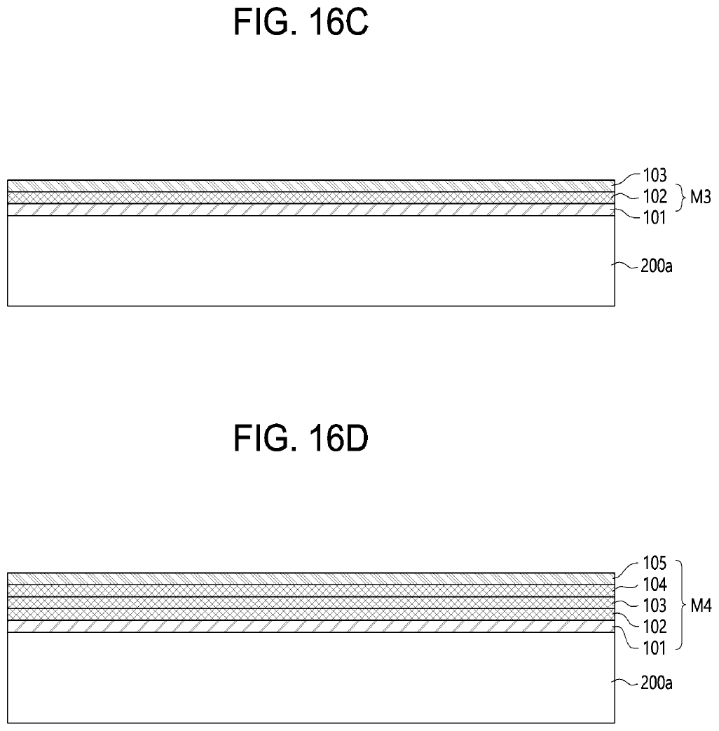

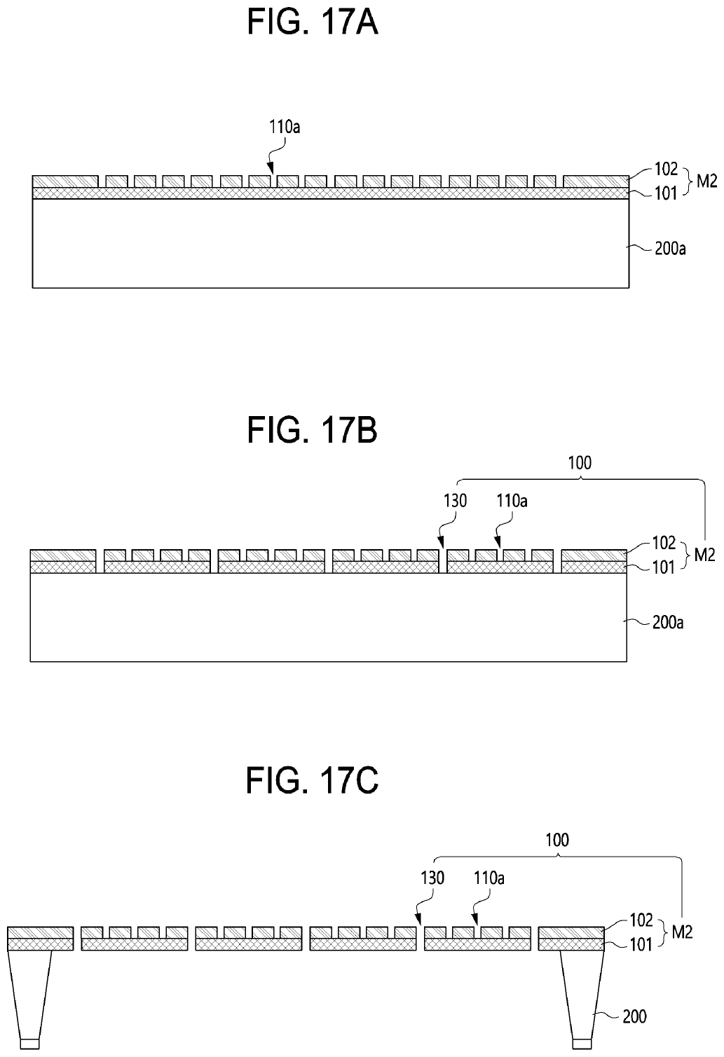

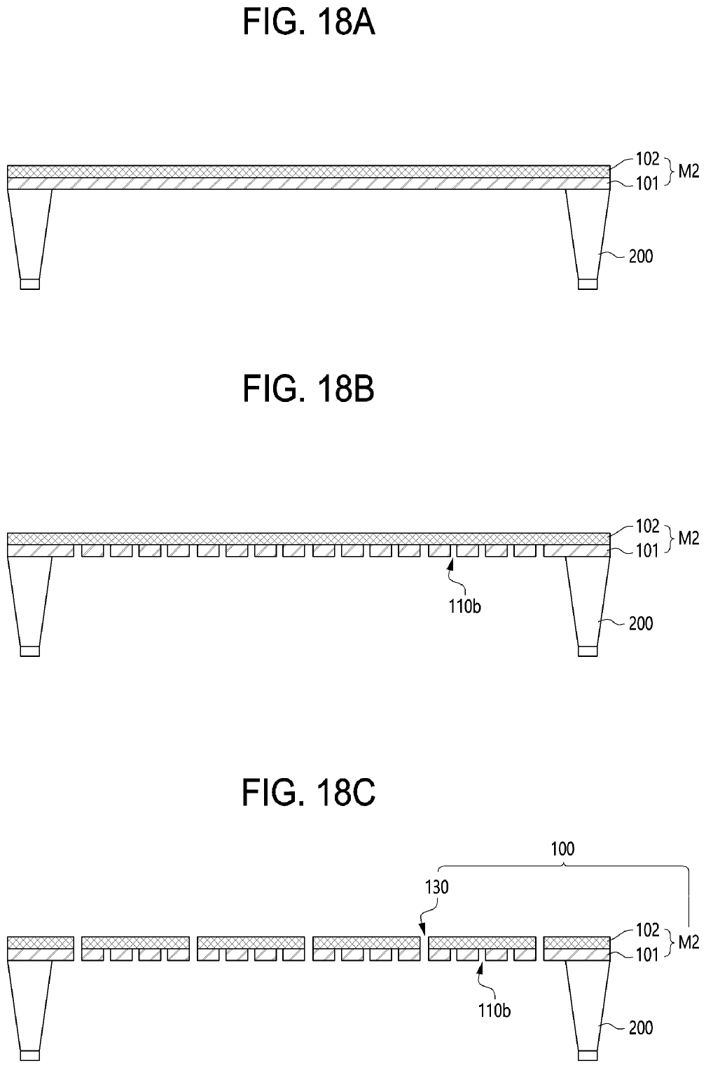

FIG. 15 is a flow chart illustrating a method of manufacturing a pellicle membrane in accordance with example embodiments, FIGS. 16A to 16D are cross-sectional views illustrating a method of manufacturing a pellicle membrane in accordance with example embodiments, FIGS. 17A to 17C are cross-sectional views illustrating a method of manufacturing a pellicle membrane in accordance with example embodiments, and FIGS. 18A to 18C are cross-sectional views illustrating a method of manufacturing a pellicle membrane in accordance with example embodiments.

Referring to FIG. 15, a method of manufacturing the pellicle assemblies 10a˜10n may include forming a membrane structure on a substrate at S100. The method may further include etching the substrate to form a pellicle membrane and forming a pellicle frame configured to support the pellicle membrane at S200.

Referring to FIGS. 16A to 16D, the membrane structures M1˜M4 may be formed on the substrate 200a.

In example embodiments, the substrate 200a may include a silicon on insulator (SOI), but embodiments of the present disclosure are not limited thereto. The substrate 200a may be etched to form the pellicle border 200.

Each of the membrane structures M1˜M4 may include a single light transmission layer (e.g., a light transmission layer 101 in FIG. 16A) or a plurality of light transmission layers (e.g., first to fifth transmission layers 101, 102, 103, 104, and 105 in FIG. 16D). For example, the light transmission layers in the membrane structures M1˜M4 may include the same material and the same thickness, or different materials and different thicknesses.

FIGS. 17A to 17C illustrate a method of manufacturing a pellicle membrane in accordance with example embodiments. Referring to FIGS. 17A, the second light transmission layer 102 may be etched to form the upper recesses 110a. In example embodiments, the first and second light transmission layers 101 and 102 may have different etching selectivities to accurately control an etch stop time.

Referring to FIGS. 17B, the first light transmission layer 101 exposed through the upper recess 110a may be etched to form the openings 130. The openings 130 may be connected to a part of the upper recesses 110a. In other words, a plurality of portions of the first light transmission layer 101 that correspond to some of the upper recesses 110a may be further etched to form the openings 130. Thus, the pellicle membrane with the openings 130 and the upper recesses 110a may be formed.

Referring to FIG. 17C, the substrate 200a may be etched to remain the substrate 200a at the edge portion of the pellicle membrane, thereby forming the pellicle border 200. Thus, the pellicle assembly 10a including the pellicle membrane 100 and the pellicle border 200 may be manufactured. In the embodiment shown in FIGS. 17A to 17C, the pellicle membrane 100 including the openings 130 has been formed before the substrate 200a is etched. Since the openings 130 allow an etchant to flow through the pellicle membrane 100, a pressure difference across the pellicle membrane 100 may be significantly reduced in the etching process.

In example embodiments, the substrate may be etched by a dry etching process or a wet etching process. The dry etching process may use a deep etcher or a xenon etcher. The wet etching process may use potassium hydroxide (KOH) or tetramethylammonium hydroxide (TMAH).

FIGS. 18A to 18C illustrate a method of manufacturing a pellicle membrane in accordance with example embodiments. Referring to FIG. 18A, the first and second light transmission layers 101 and 102 may be stacked on the substrate 200 to form the membrane structure M2. The substrate 200 may be etched to remain the substrate 200 at the edge portion of the pellicle structure M2, thereby forming the pellicle border 200. Thus, the lower surface of the first light transmission layer 101 may be exposed.

Referring to FIG. 18B, the first light transmission layer 101 of the membrane structure M2 may be etched to form the lower recess 110b. Thus, the second light transmission layer 102 may be exposed through the lower recess 110b.

Referring to FIG. 18C, the second light transmission layer 102 exposed through the lower recesses 110b may be etched to form the openings 130 to complete the pellicle membrane 100 including the openings 130 and the lower recesses 110b. In other words, a plurality of portions of the second light transmission layer 102 that correspond to some of the lower recesses 110b may be etched to form the openings 130.

In example embodiments, the upper recess, or the lower recess, or both may be formed at a single light transmission layer. Alternatively, the upper recess and the lower recess may be formed by a plurality of etching processes.

According to example embodiments, the pellicle membrane may include the recess and the opening to decrease an absorption amount of an EUV light and to improve a mechanical property of the pellicle membrane. The pellicle membrane may buffer an impact caused by a pressure difference so that the pellicle membrane may not be easily broken to extend a lift span of the pellicle membrane.

The above-described embodiments of the present disclosure are intended to illustrate and not to limit various embodiments of the present disclosure. Various alternatives and equivalents are possible. Various embodiments of the present disclosure are not limited by the embodiments described herein. Nor are embodiments of the present disclosure limited to any specific type of semiconductor device. Another additions, subtractions, or modifications are possible.

What is claimed is:

1. A pellicle assembly comprising:
a pellicle membrane including an upper surface and a lower surface that face each other and are spaced apart from each other by a first depth, at least one recess extending from one or both of the upper surface and the lower surface by a second depth, the second depth being smaller than the first depth, and at least one opening penetrating from the upper surface to the lower surface; and
a pellicle border configured to support the pellicle membrane.

2. The pellicle assembly of claim 1, wherein the pellicle membrane comprises at least one light transmission layer.

3. The pellicle assembly of claim 1, wherein the pellicle membrane comprises a plurality of light transmission layers which are stacked, and the plurality of light transmission layers each have a substantially same thickness and include a same material.

4. The pellicle assembly of claim 1, wherein the pellicle membrane comprises a plurality of light transmission layers which are stacked, and at least one of the plurality of light transmission layers comprises a material different from that of remaining light transmission layers.

5. The pellicle assembly of claim 4, wherein at least one of the light transmission layers comprises a carbon-containing layer, the carbon-containing layer including at least one of graphene, graphite and carbon nanotube.

6. The pellicle assembly of claim 5, wherein the carbon-containing layer is a central light transmission layer among the plurality of light transmission layers which are stacked.

7. The pellicle assembly of claim 1, wherein the at least one opening is located at an edge region of the pellicle membrane adjacent to the pellicle border.

8. The pellicle assembly of claim 1, wherein the at least one recess includes a plurality of recesses, and the plurality of recesses have different depths each being smaller than the first depth.

9. The pellicle assembly of claim 1, wherein the at least one opening includes a plurality of the openings spaced apart from each other by a first gap within the pellicle membrane,
wherein the at least one recess includes a plurality of recesses spaced apart from each other by a second gap within the pellicle membrane, and
wherein the second gap is smaller than the first gap.

10. The pellicle assembly of claim 1, wherein the recess has an outer hole and an inner hole, and a diameter of the outer hole is different from a diameter of the inner hole.

11. The pellicle assembly of claim 1, wherein the recess comprises an upper recess extending from the upper surface toward the lower surface, and
wherein a diameter of the upper recess decreases towards the lower surface.

12. The pellicle assembly of claim 1, wherein the recess comprises a lower recess extending from the lower surface toward the upper surface, and
wherein a diameter of the lower recess decreases towards the upper surface.

13. The pellicle assembly of claim 1, wherein a ratio of a total area occupied by the at least one opening to an entire area of one of the upper surface and the lower surface is in a range from 1% to 9%.

14. A pellicle membrane comprising:
a light transmission layer;
a plurality of openings penetrating through the light transmission layer; and
a plurality of recesses disposed between adjacent openings among the plurality of openings, the plurality of recesses having at least one depth.

15. The pellicle membrane of claim 14, wherein the light transmission layer has a first surface and a second surface opposite to the first surface, and the recesses comprise a first recess having a first depth from the first surface and a second recess having a second depth from the second surface.

16. The pellicle membrane of claim 15, wherein the light transmission layer is a first light transmission layer, the membrane further comprising a second light transmission layer interposed between the first recess and the second recess.

17. The pellicle membrane of claim 16, wherein the second light transmission layer comprises a carbon-containing layer including at least one of graphene, graphite and carbon nanotube.

18. The pellicle membrane of claim 16, wherein the first recess faces the second recess.

19. The pellicle membrane of claim 16, wherein the first recess and the second recess are alternately arranged.

20. A method of manufacturing a pellicle assembly, the method comprising:
forming at least one light transmission layer on a substrate;
etching the at least one light transmission layer to form at least one recess;
etching the light transmission layer to form at least one opening, thereby defining a pellicle membrane; and
etching the substrate to form a pellice border at an edge portion of the pellicle membrane.
